(19) United States
(12) Patent Application Publication
(10) Pub. No.: US 2008/0145999 A1
(43) Pub. Date: Jun. 19, 2008

(54) METHOD FOR MANUFACTURING A SEMICONDUCTOR DEVICE

(75) Inventor: Juri KATO, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/954,472

(22) Filed: Dec. 12, 2007

(30) Foreign Application Priority Data
Dec. 19, 2006 (JP) 2006-341645

(51) Int. Cl. H01L 21/76

(52) U.S. Cl. 438/401; 257/E21.54

(57) ABSTRACT

A method of a semiconductor device comprises: a) depositing a first semiconductor layer and a second semiconductor layer in a semiconductor substrate in series; b) forming a first groove penetrating the first and second semiconductor layers and placed adjacent to an element region by partly etching the first and second semiconductor layers; c) forming a supporting member that supports the second semiconductor layer and covers over the second semiconductor layer and is embedded into the first groove; d) forming a second groove that exposes the first semiconductor layer from the bottom of the second semiconductor layer supported by the supporting member and is placed near the element region; and e) forming a cavity between the semiconductor substrate and the second semiconductor layer in the element region by etching the first semiconductor layer via the second groove under a specific condition in which the first semiconductor layer is easily etched, compared to the second semiconductor layer. Step b) further comprises: forming an alignment mark on the semiconductor substrate while forming the first groove by photolithography and etching for forming the first groove. Step d) further comprises aligning the position of photolithography by using the alignment mark.

The entire disclosure of Japanese Patent Application No. 2006-341645, filed Dec. 19, 2006 is expressly incorporated by reference herein.

### BACKGROUND OF THE INVENTION

1. Technical Field

Several aspects of the present invention relates to a method of manufacturing a semiconductor device. In particular, it relates to a technology of partly forming a SOI structure on a semiconductor substrate, in which a SOI layer is formed with reducing fluctuation of areas and plain configurations.

2. Related Art

JP-A-2005-354024 and JP-A-2006-41331 disclose this technology and a method of partly forming a SOI structure on a bulk substrate (namely a SBSI method), attaining low cost for forming a SOI transistor. According to the SBSI method, Si and SiGe layers are formed on the Si substrate and a supporting hole h′, which penetrates through Si and SiGe layers and reaches the SI substrate, is formed as shown in FIG. 15A. Next, as shown in FIG. 15B, a supporting film 122 is formed on an entire surface of the Si layer while embedding a material of the film into the supporting hole h′. Then, as shown in FIG. 15C, a groove H′ (a hole for removing the SiGe material), which exposes the side surface of the SiGe layer from the lower surface of the Si layer supported by the supporting member 122, is formed. Next, a cavity is formed between the Si layer and the Si substrate by wet-etching the SiGe layer via the hole H′ for removing SiGe. Then a box layer composed of a SiO₂ layer and the like is formed between the Si substrate and the Si layer by thermal oxidization or CVD. The conventional SBSI method, the area of the Si layer (namely an element region) formed on the BOX layer is not so large and the configuration of it from a plain view has small aspect ratio and a simple rectangle.

The current trend, however, shows a large area for elements accompanied with increasing a selective ratio of etching SiGe to Si. Further, wide application of the SBSI method such as manufacturing SRAM and the like makes the configuration of an element region from a plain view (called as plain configuration) complicated. For example, as a plain configuration for an element region, a rectangle having an extra long side and an extra short side, an L shape, a + shape, and a ≡ shape are selected. Further, areas of this configuration include many varieties such as large and small. As shown in FIG. 15C, in the conventional method, the Si layer was sufficiently supported if the supporting hole h′ is placed only on the short side of an element region. On the other hand, there is currently needed a case in which supporting holes are placed on not only the short side but the long side in order to sufficiently support the Si layer.

Further, in the conventional method, misaligning positions of the supporting hole h′ and the hole H′ for removing SiGe together a little does not substantially affect an area of an element region and its plane configuration. However, there recently increases a case in which such misaligning of the positional relationship between the supporting hole h′ and the hole H′ for removing SiGe a little greatly varies an area of an element region and its plain configuration. As shown in FIG. 16A and indicated as a thick line, for example, if a gate electrode 141 of a MOS transistor is arranged in parallel with a short side of a element region and so as to pass directly over the supporting hole h′1 aligned along the long side of the element region, the channel width W of the MOS transistor becomes equal to a space between the supporting hole h′ and the hole H′ for removing SiGe. Here, as shown in FIG. 16B, the supporting hole h′ is downwardly misaligned. Otherwise, as shown in FIG. 16C, the channel width becomes shortened if the supporting hole h′ is upwardly misaligned.

### SUMMARY

An advantage of the present invention is to provide a method of manufacturing a semiconductor device to overcome the above issue newly revealed as development of the SBSI method. The method is able to reduce variation of area and configuration of a SOI layer when the SOI layer is formed on a semiconductor substrate.

According to an aspect of the invention, a method of manufacturing a semiconductor device includes: a) depositing a first semiconductor layer and a second semiconductor layer in a semiconductor substrate in series; b) forming a first groove penetrating the first and second semiconductor layers and placed adjacent to an element region by partly etching the first and second semiconductor layers; c) forming a supporting member that supports the second semiconductor layer, covers over the second semiconductor layer and is embedded into the first groove; d) forming a second groove that exposes the first semiconductor layer from the bottom of the second semiconductor layer supported by the supporting member and is placed near the element region; and e) forming a cavity between the semiconductor substrate and the second semiconductor layer in the element region by etching the first semiconductor layer via the second groove under a specific condition in which the first semiconductor layer is easily etched, compared to the second semiconductor layer. Step b) further comprises: forming an alignment mark on the semiconductor substrate while forming the first groove by photolithography and etching for forming the first groove. Step d) further comprises: aligning the position of photolithography by using the alignment mark.

In the conventional SBSI method, the configuration of a element region was relatively simple and misaligning the second groove (namely a hole for removing SiGe) with the first groove (namely a supporting hole) a little did not affect an area of an element region and its configuration. Hence, the positional relationship between the first groove and the second groove was not paid attention. Therefore, both the first groove and the second groove were aligned while arbitrary patterns in a previous process worked as a mark for them. For example, in manufacturing a hybrid semiconductor device including a SOI structure and a bulk structure, a LOCOS structure for isolating elements in a bulk is worked as a mark for aligning these grooves.

On the other hand, according to the first aspect of the invention, the first groove and an alignment mark are simultaneously patterned with a same photo mask and the second groove is patterned while this alignment mark works as a mark. Namely, in the process of forming the second groove, the second groove is aligned as the first groove working as a reference, instead of LOCOS, reducing misalignment of location of the second groove to the first location compared to a case in which LOCOS works as a reference. Accordingly, the second semiconductor layer is formed as an element region surrounded by the first and second grooves while reducing fluctuation of its area and configuration.

According to the aspect of the invention, the first and second grooves may be formed so as to sandwich a region to be a channel in the element region from a plain view. In case when a region to be a channel (also called as a channel region) is sandwiched between the first and second grooves from a plain view, if the position of the second groove is misaligned to that of the first groove, the length of the channel region, namely an actual channel width may be out of the predetermined value. The above method, however, reduces misalignment of the position of the second groove to the first groove, contributing to reduction of fluctuation about the channel width W.

According to the aspect of the invention, the first and second grooves may be formed and adjacently located together so as to sandwich the element region from a plain view and to overlap the second groove with the end of the first groove at the interface between the first groove and the second groove.

In the above method, the second semiconductor layer at the interface in which the first groove and second groove are adjacently located, can be etched and removed by at least one of processes for forming the first groove or forming the second groove. Namely, residual of etching can be avoided. Accordingly, short circuiting among element regions (namely defects of element isolation) due to the residual of the second semiconductor etching can be avoided.

According to the aspect of the invention, step b) may further comprise: forming the first groove near a region within an element region to be a channel region; and forming a gate electrode from an area directly above a region to be a channel region to another area directly above the first groove near the region to be a channel region. The length of the first groove along the first groove formed near the region to be the channel region is longer than the gate length of the gate electrode. This method can maintain the channel length a predetermined value even if the position of the configuration of the gate electrode is misaligned a little, contributing to stabilization of a transistor.

### BRIEF DESCRIPTION OF THE DRAWINGS

The invention will be described with reference to the accompanying drawings, wherein like numbers reference like elements.

FIG. 1 shows a method of manufacturing a semiconductor device regarding a first embodiment (first.)

FIG. 2 shows the method of manufacturing a semiconductor device of the first embodiment (second.)

FIG. 3 shows the method of manufacturing a semiconductor device of the first embodiment (third.)

FIG. 4 shows the method of manufacturing a semiconductor device of the first embodiment (fourth.)

FIG. 5 shows the method of manufacturing a semiconductor device of the first embodiment (fifth.)

FIG. 6 shows the method of manufacturing a semiconductor device of the first embodiment (sixth.)

FIG. 7 shows the method of manufacturing a semiconductor device of the first embodiment (seventh.)

FIG. 8 shows the method of manufacturing a semiconductor device of the first embodiment (eighth.)

FIG. 9 shows the method of manufacturing a semiconductor device of the first embodiment (ninth.)

FIG. 10 is a diagram showing alignment of a photo mask 90 using an alignment mark M.

FIG. 11 is a diagram showing an example of a configuration of an element region regarding other embodiment (first.)

FIG. 12 is a diagram showing an example of a configuration of an element region regarding other embodiment (second.)

FIG. 13 is a diagram showing an example of a configuration of an element region regarding other embodiment (third.)

FIG. 14 is a diagram showing an example of a configuration of an element region regarding other embodiment (fourth.)

FIG. 15 shows a conventional technology.

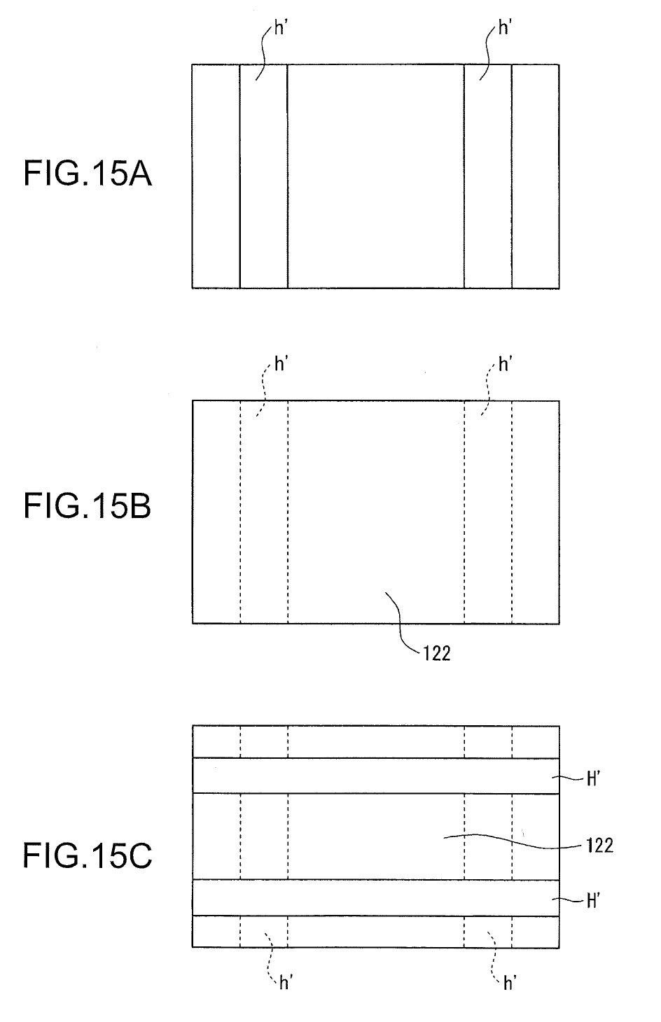

FIG. 16 shows a disadvantage in the conventional technology.

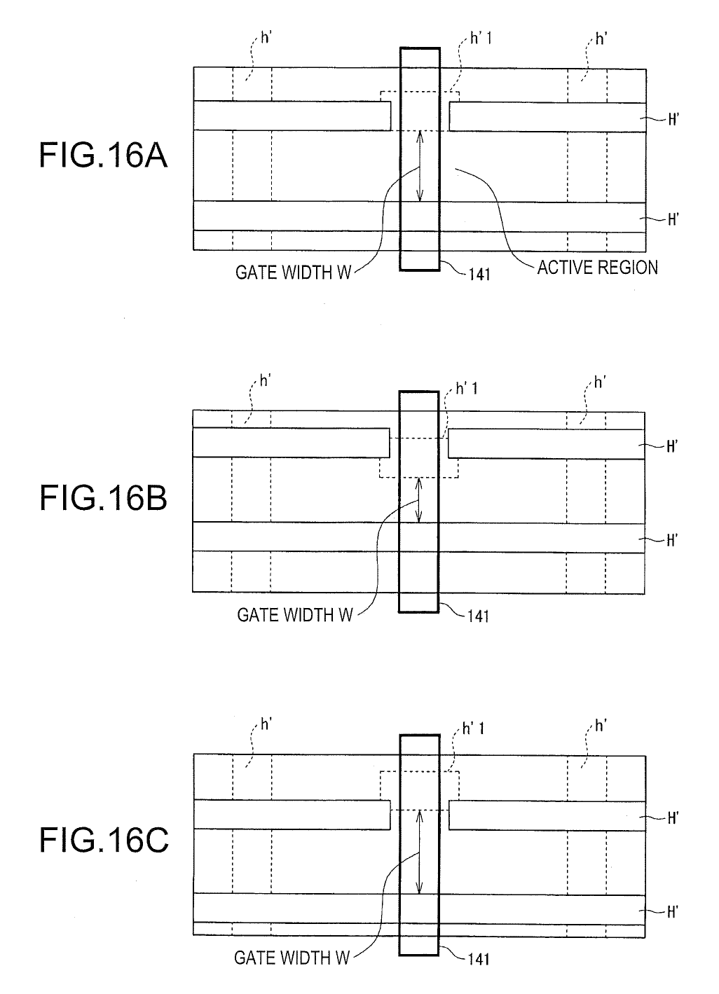

### DESCRIPTION OF EXEMPLARY EMBODIMENTS

Embodiments of the invention will now be described with reference to the accompanying drawings.

### First Embodiment

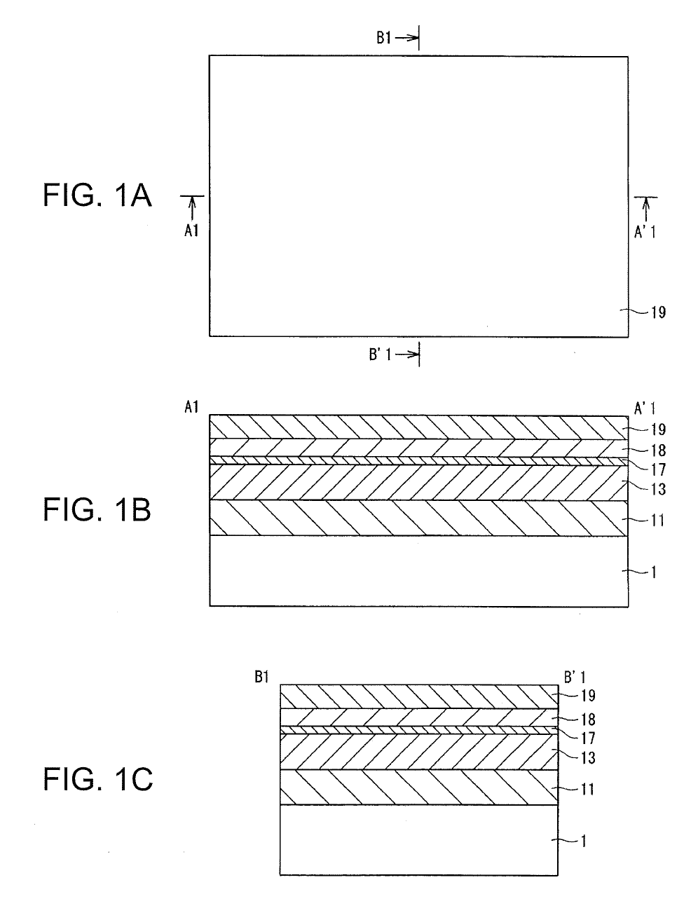

FIG. 1 to FIG. 9 show a method of manufacturing a semiconductor device of a first embodiment of the invention. FIG. 1A to FIG. 9A are plain views, FIG. 1B to FIG. 9B are cross sections along the lines A1-A1′ to A9-A9′ of FIG. 1A to FIG. 9A, and FIG. 1C to FIG. 9C are cross sections along the lines B1-B1′ to B9-B9′ of FIG. 1C to FIG. 9C.

First, as shown in FIGS. 1A to 1C, a mono crystalline silicon buffer layer not shown in the figure is formed on a Si substrate 1, then, a mono crystalline silicon germanium (SiGe) layer 11 is formed on it, further, a mono crystalline silicon (Si) layer 13 is formed on it. These Si buffer layer, Si Ge layer 11 and Si layer 13 are continuously grown by an epitaxial growing method, for example. Next, a SiO₂ layer 17 is formed on an entire surface of the Si substrate 1, a silicon nitride (Si₃ N₄) layer 18 is formed on it and further, a SiO₂ layer 19 is formed on it. These SiO₂ layer 17, (Si₃ N₄) layer 18 and SiO₂ layer 19 are formed by CVD.

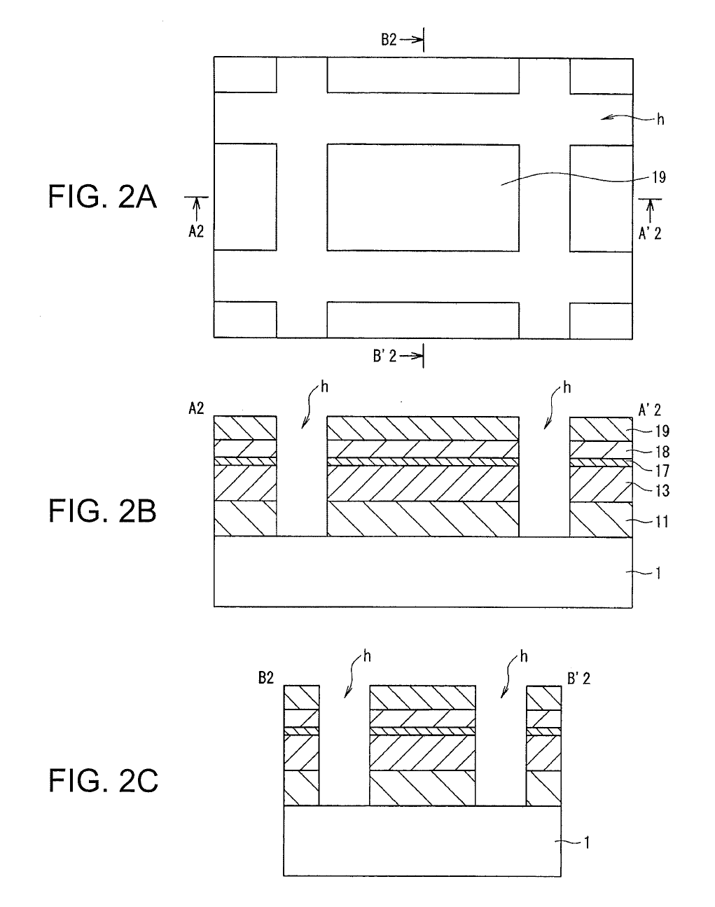

Next, as shown in FIGS. 2A to 2C, these SiO₂ layer 17, Si₃ N₄ layer 18, SiO₂ layer 19, Si buffer layer (not shown), Si Ge layer 11 and Si layer 13 are partly etched by photolithography and etching technology. As shown in FIGS. 2A to 2C, this etching forms a supporting hole h that reaches the surfaces of the Si substrate in a region, which is overlapped with an element isolation region (namely a region where a SOI structure is not formed) from a plain view. In the etching process, etching may be stopped at the surface of the Si substrate 1, or the Si substrate 1 may be excessively etched, forming a recess.

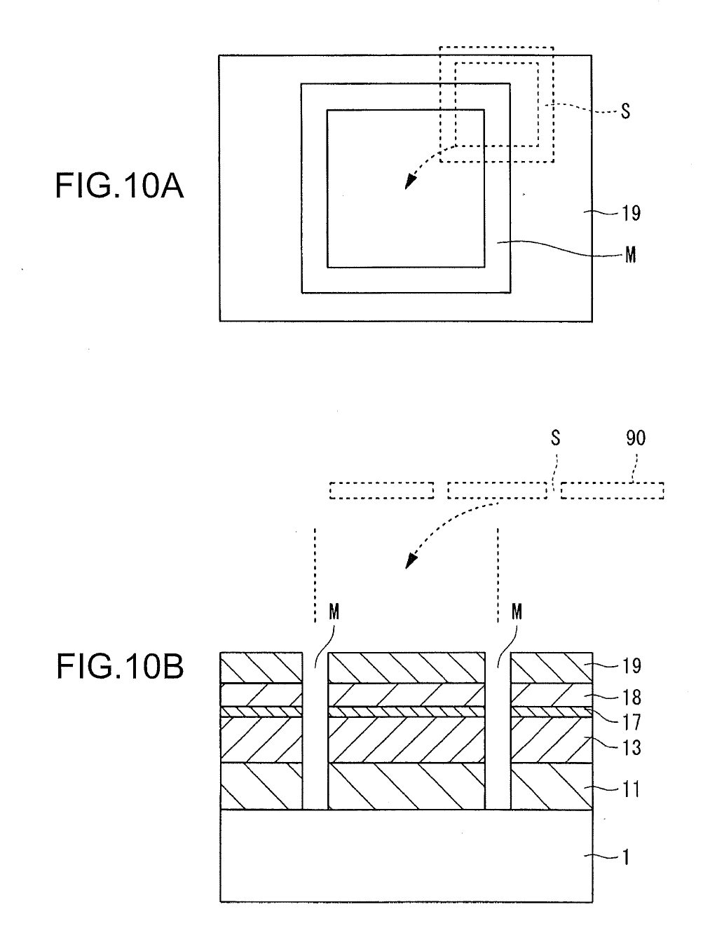

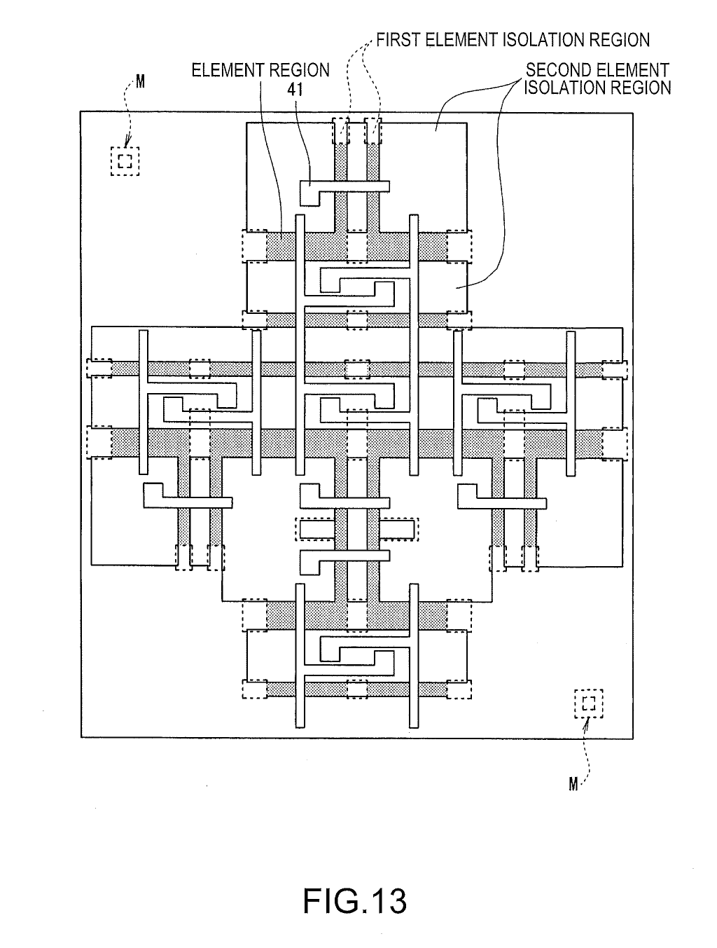

Here, in the embodiment, a photo mask including a slit for forming an alignment mark is used for forming a supporting hole h. Using this photo mask forms an alignment mark M shown in FIGS. 10A and 10B while forming the supporting hole h. The plain configuration of the alignment mark M may be a square pattern having a hollow shown in FIG. 10A, or a cross shape, or preferably any other shapes including a line toward X direction and another line crossing the line and directing toward Y direction. The alignment mark M may be arbitrary placed in a position such as the corner of a wafer, a scribe line, and an element isolation region. Numbers of the alignment mark M are also arbitrary. For example, in a layout of a SRAM cell 5 shown in FIG. 13, a single piece of the alignment mark M may be placed in the element isolation region on the upper left and the element isolation region on the lower right.

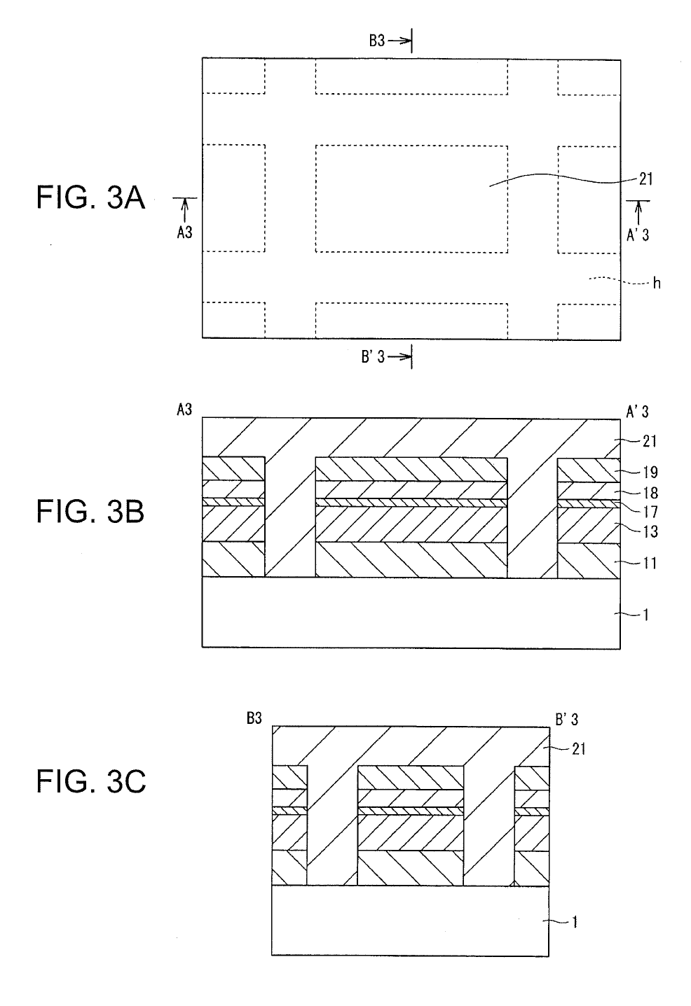

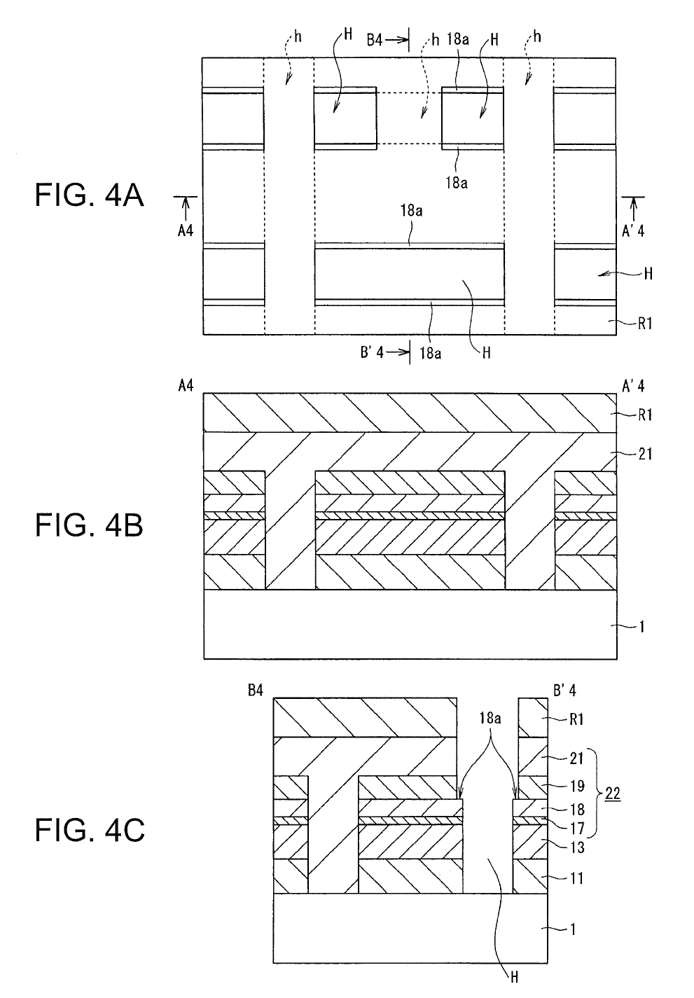

After forming the supporting hole h with the alignment mark M simultaneously, a resist pattern not shown in the figure is removed. Then, as shown in FIGS. 3A to 3C, a SiO₂ film 21 is formed on an entire surface of the Si substrate 1 while such film is embedded into the supporting hole h. The SiO₂ film 21 is formed by CVD for example. Then, as shown in FIGS. 4A to 4C, a resist pattern R1 is formed on the SiO₂ film 21 and the SiO₂ films 19 and 21 are partly etched by using the resist pattern R1 as a mask. This etching may be dry etching having high selective ratio of a Si₃ N₄ film (namely remarkably high etching rate for a SiO₂ film to a Si₃ N₄ film) or fluorinated acid wet-etching having high selective ratio for the Si₃ N₄ film. As shown in FIGS. 4A to 4C, this etching forms a supporting member 22 composed of the SiO₂ films 17, 19 and 21 and the Si₃ N₄ film 18 while forming a groove H (a hole for removing SiGe) that reaches the surface of the Si substrate. In the etching for forming the groove H for removing SiGe, etching may be stopped at the surface of the Si substrate 1, or the Si substrate 1 may be over etched, forming a recess.

In the embodiment, when forming the resist pattern R1, a photo mask is aligned to a wafer by making an alignment mark work as a mark instead of LOCOS (not shown in the figure). The alignment mark was formed at the time of forming the supporting hole h. As shown in FIGS. 10A and 10B, a slit S for alignment is formed in a photo mask 90 for forming a hole H to remove SiGe and corresponds to the alignment mark M. The photo mask 90 is aligned to the wafer so as to fix the slit S within the alignment mark M from a plain view. This alignment forms the hole H for removing SiGe without displacement from the supporting hole h. Further, as shown in FIG. 4C, side surfaces of the SiGe layer 11 and the Si layer 13 can be exposed to the inside wall of the hole H for removing SiGe.

Here, the plain configuration of the slit S formed in the photo mask 90 may be a square pattern having a hollow shown in FIGS. 10A and 10B, or a cross shape, or preferably any other shapes including a line toward X direction and another line crossing the line and directing toward Y direction. If the plain configuration of the slit S is similar to the plain configuration of the alignment mark M and these configurations include lines along X and Y directions, adjustment accuracy of the photo mask with the wafer can be kept superior level without no displacement along X and Y directions.

Here, as shown in FIG. 4C, the resist mask R1 formed by the photo mask 90 may be opened directly above the region and periphery of it for forming the hole H for removing SiGe, and closed above the other areas. As shown in FIGS. 4A and 4C, using the resist pattern R1 having such configuration and etching the SiO₂ films 19 and 21 expose an end portion 18a of the Si₃N₄ film 18 from the resist pattern R1. After exposing the end portion 18a, the SiO₂ film 21 (embedded into the supporting hole h) is etched while the end portion 18a works as a mask. In this case, even if the resist pattern R1 is displaced a little, the hole H for removing SiGe located at the lower side from the SiO₂ film 19 is formed as well as self-aligned, bringing some margins toward the permitted error for aligning the resist mask R1.

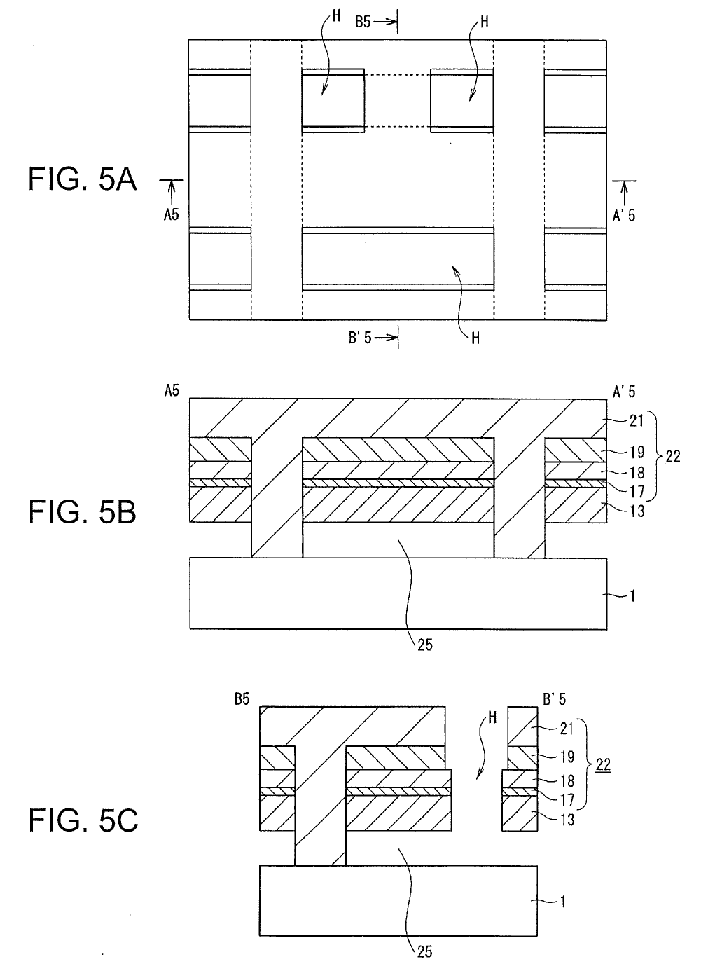

Next, the fluorinated nitric acid solution is applied to and contacted with the side surfaces of the SiGe layer 11 and the Si layer 13, via the hole H for removing SiGe, selectively etching and removing the SiGe layer 11. As shown in FIGS. 5A to 5C, this etching forms the cavity 25 between the Si layer 13 and the Si substrate 1. Here, etching rate of SiGe is larger than that of Si (namely selective ratio of etching SiGe to Si is about 400 to 1000), making it possible to etch and remove only the SiGe layer 11 while leaving the Si layer 13 in this wet etching using a fluorinated nitric acid solution. After forming the cavity 25, the upper surface and side surface of the Si layer 13 are supported by the supporting member 22.

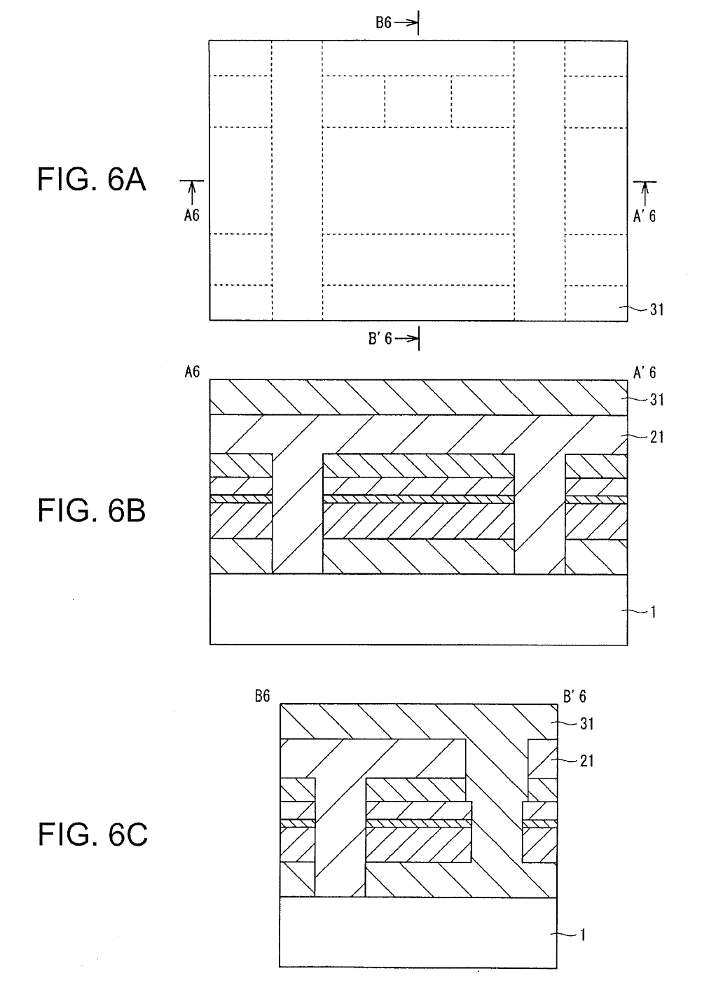

Next, in FIGS. 5A to 5C, the Si substrate 1 is thermally oxidized, forming a SiO₂ film (not shown in the figure) on the surfaces of the Si substrate 1 and the Si layer 31 facing the cavity 25. Then, as shown in FIGS. 6A to 6C, the insulating film 13 is formed on an entire surface of the Si substrate by CVD, for example, and embedded into the hole H for removing SiGe. The insulating film 31 is a SiO₂ film or a Si₃N₄ film. Theses thermal oxidization and CVD embed an insulating film such as SiO₂ into the cavity 25.

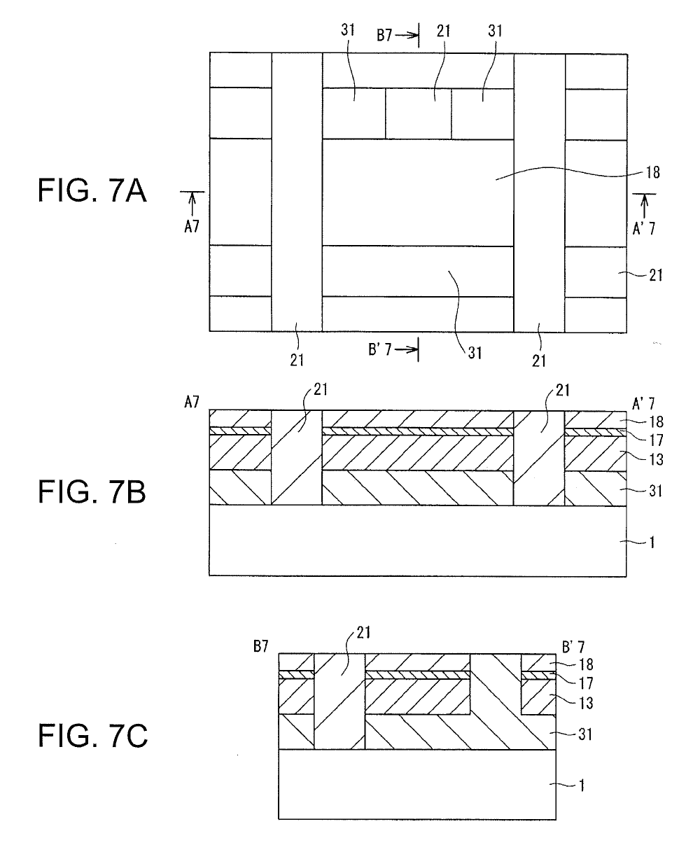

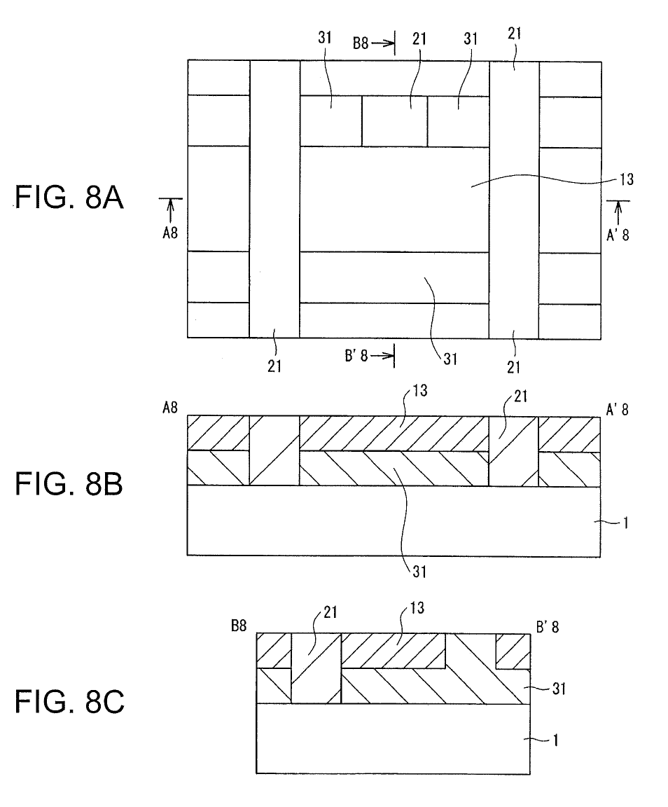

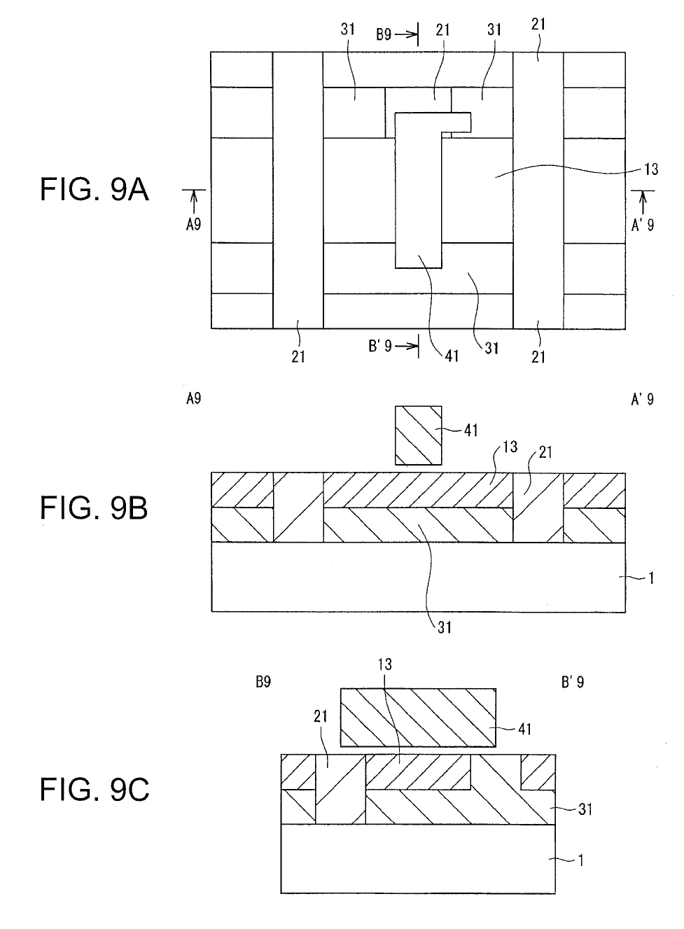

Then, the insulating film 31 and the SiO₂ films 19 and 21 covering over an entire surface of the Si substrate 1 are planarized and removed by CMP for example. Then, the surface of the Si₃N₄ film is exposed as shown in FIGS. 7A to 7C. The Si₃N₄ film 18 works as a stopper against polishing pad in CMP. Next, the Si₃N₄ film 18 is removed by wet etching with thermal phosphoric acid. Further, the SiO₂ film 13 is removed by wet etching with dilute fluoric acid, exposing the surface of the Si layer 13 shown in FIG. 8A to 8C. This process completes the SOI structure on the Si substrate. Then, as shown in FIGS. 9A to 9C, a gate electrode 41 is formed on the SOI structured Si layer 13 via a gate insulating layer (not shown) forming a MOS transistor.

According to the embodiment, the supporting hole h and the alignment mark M are simultaneously patterned by the same photo mask and the hole H for removing SiGe is patterned while the alignment mark works as a mask. Namely, in the process of forming the hole H for removing SiGe, the hole H is aligned as the supporting hole h working as a reference, instead of LOCOS, reducing misalignment of location of the hole H to the supporting hole h compared to a case in which LOCOS works as a reference. This alignment reduces variation of an area and configuration of the Si layer (namely the SOI layer) 13 in the region surrounded by the supporting hole h and the hole H for removing SiGe. Further, the surface area of the supporting hole 22 can be widened and variation of a plain configuration of the supporting member can be small, making it possible to stably perform selective etching of SiGe and embed insulating material into a hole.

In the embodiment, the Si₃N₄ film 18 is placed between the Si layer 13 and the SiO₂ layer 21, avoiding etching the Si layer 13 in the element region when the hole H for removing SiGe is formed. But, in the invention, the Si₃N₄ film 18 is not indispensable. The SiO₂ film may be formed directly on the Si layer 13 by omitting the process for forming the Si₃N₄ film 18 and the SiO₂ film 17. The reason is that the hole for removing SiGe is aligned while the alignment mark M formed at the same time of forming the supporting hole h works as a mark. This alignment reduces displacement of the hole H for removing SiGe from the supporting hole h, reducing variation of an area and a plain configuration of an element region even if forming the Si₃N₄ film 18 is omitted for example.

### 2) Other Embodiment

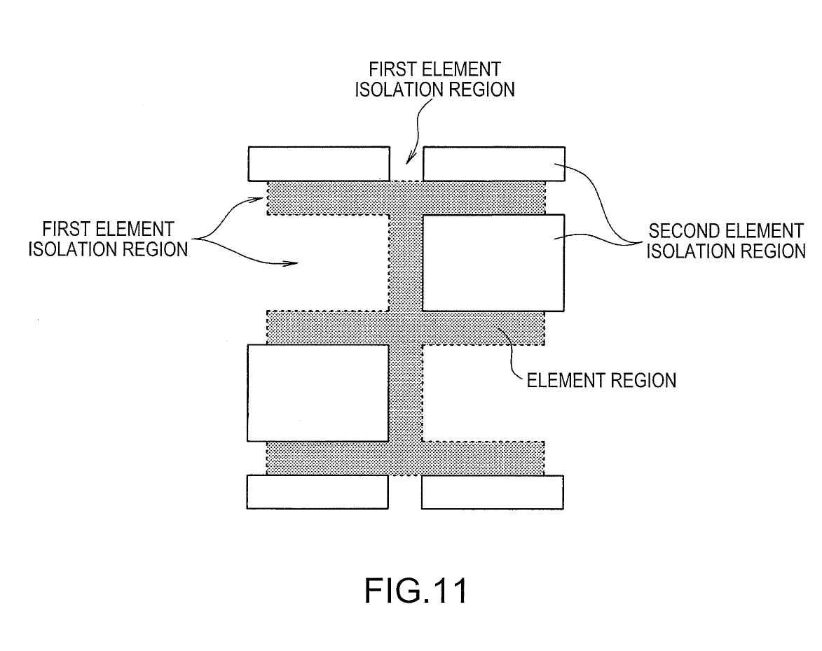

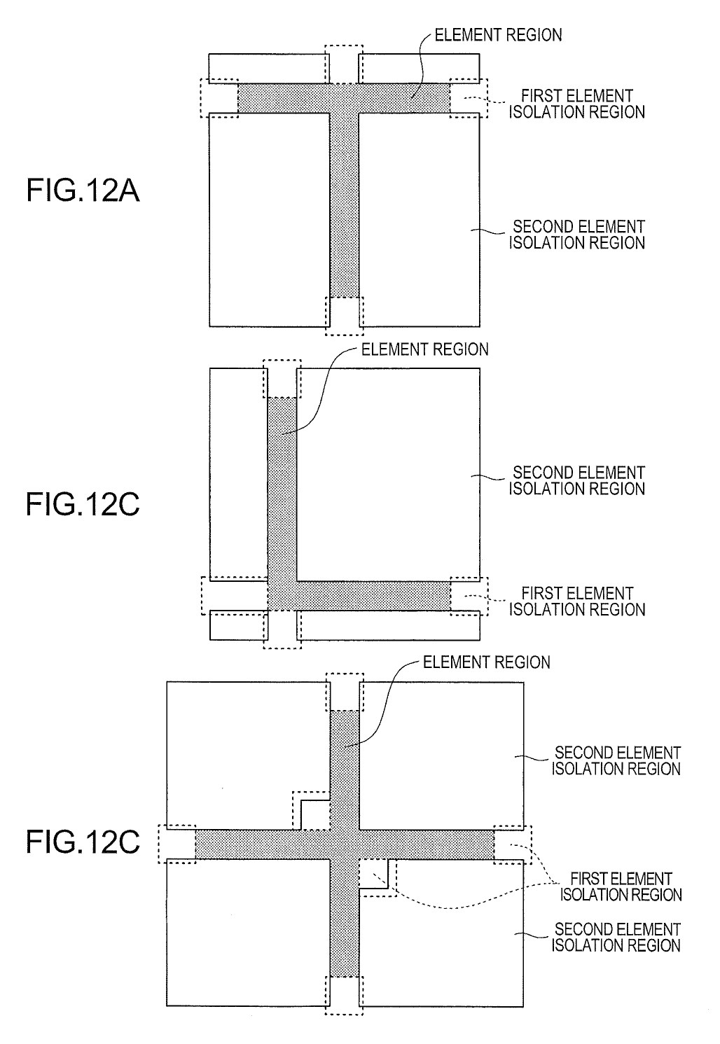

In the first embodiment, a plain configuration of the element region surrounded by the supporting hole h and the hole H for removing SiGe is a rectangular shape having sufficiently long side. But the plain configuration is not limited to this. For example, the shape of an element region may be a ≡ shape. Otherwise, as shown in FIGS. 12A to 12C, the shape of an element region may be a T shape, a L shape or a + shape. In FIG. 11, a region surrounded by a dot line is an element region. A region outside from a dot line is a region for forming the supporting hole h (a first element isolation region) and a region surrounded by a solid line is a region for forming the hole H for removing SiGe (a second element isolation region.) In FIGS. 12A to 12C, a region surrounded by a dot line is an region for forming the supporting hole h (namely the first element isolation region.) a region surrounded by a solid line is a region for forming the hole H for removing SiGe (a second element isolation region.) and a region surrounded by a dot and solid lines is an element region.

As shown in FIG. 11 and FIGS. 12A to 12C, even if a plain configuration of an element region has one of any shapes such as a T shape, a L shape, a + shape and a ≡0 shape, the hole H for removing SiGe is patterned with using the alignment mark M (shown in FIGS. 10A and 10B for example) formed simultaneously with the supporting hole h. This patterning reduces displacement of the hole H for removing SiGe from the supporting hole h and reduces variation of an area and a configuration of the element region.

Further, as shown in FIGS. 12 A to 12C, when the first isolation region is placed at a position adjacent to the second isolation region so as to surround the element region, the end portion of the first isolation region may be overlapped with the end portion of the second isolation region (by at least a distance of an alignment margin) near the interface area between the both regions. Here, the distance of an alignment margin is a distance which is larger than alignment error permitted in photolithography. This overlapping removes the Si layer 13 that is not preferably left (see FIG. 4C) by etching with high reproduction near the interface area between the both regions, avoiding electrical short circuit (an element isolation defect) between the Si layers 13 due to their residue after etching. A layout of the SRAM cell 5 shown in FIG. 13 may have a combination of element regions shown in FIG. 12.

Here, as shown in FIG. 11 and FIGS. 12 A to 12 C, when the element region has a one of configurations such as a T shape, a L shape, a + shape and a ≡ shape, supporting the Si layer by the end area of the element region seen from a plain view may be weakened. In such case, the supporting hole h may be placed at a position near the end area of the element region and support the side of the Si layer in the element region. This placement extinguishes the weak portion for supporting the Si layer in the element region, avoiding sticking at the time of etching SiGe due to insufficient supporting and avoiding bent and deformation of the Si layer at the time of embedding the cavity and forming the insulating film.

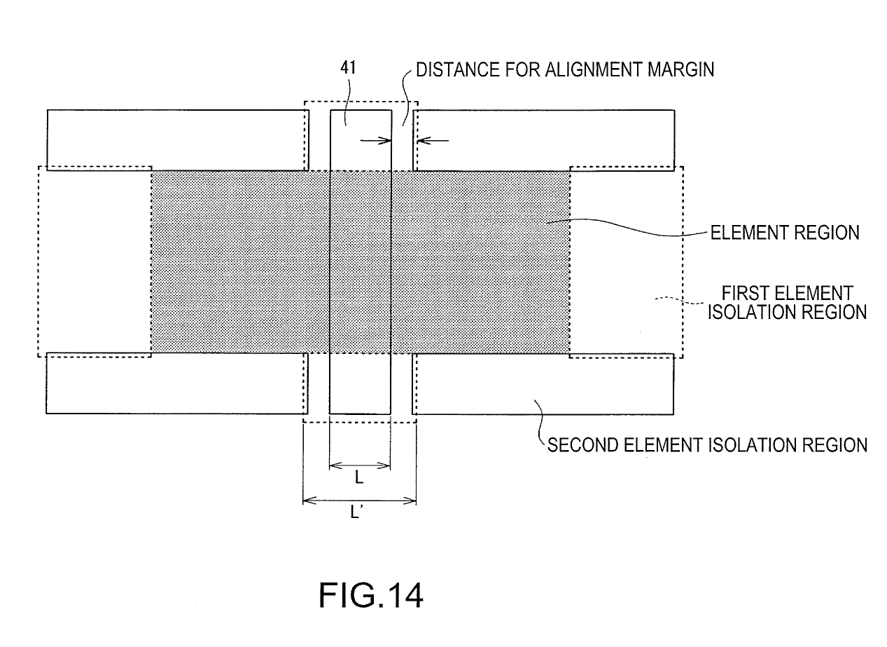

Further, as shown in FIG. 14, in a case when at least a part of the first element isolation region is placed near the channel region and the gate electrode 14 is formed from the channel region to the first element isolation region near the channel region, the length L′, the length of the first element isolation region along the channel length may be longer than the length L, the gate length of the gate electrode 41 (by at least the distance of a alignment margin.) Such length of the first isolation region can maintain the channel width W a predetermined value even if the position of the configuration of the gate electrode is misaligned a little, contributing to stabilization of a transistor.

In the embodiment, the Si substrate 1 corresponds to a semiconductor substrate of the invention, the SiGe layer 11 corresponds to a first semiconductor layer of the invention and the Si layer 12 corresponds to the second semiconductor layer of the invention. Further, the supporting hole h corresponds to the first groove and the hole H for removing SiGe corresponds to the second groove in the invention.

What is claimed is:

1. A method of a semiconductor device comprising:
a) depositing a first semiconductor layer and a second semiconductor layer in a semiconductor substrate in series;
b) forming a first groove penetrating the first and second semiconductor layers and placed adjacent to an element region by partly etching the first and second semiconductor layers;
c) forming a supporting member that supports the second semiconductor layer and covers over the second semiconductor layer and is embedded into the first groove;
d) forming a second groove that exposes the first semiconductor layer from the bottom of the second semiconductor layer supported by the supporting member and is placed near the element region; and
e) forming a cavity between the semiconductor substrate and the second semiconductor layer in the element region by etching the first semiconductor layer via the second groove under a specific condition in which the first semiconductor layer is easily etched, compared to the second semiconductor layer, wherein
step b) further comprises: forming an alignment mark on the semiconductor substrate while forming the first groove by photolithography and etching for forming the first groove, wherein
step d) further comprises aligning the position of photolithography by using the alignment mark.

2. The method of a semiconductor device according to claim 1, wherein
the first groove and the second groove are formed so as to sandwich a region within the element region to be channel region from a plain view.

3. The method of a semiconductor device according to claim 1, wherein the first groove and the second groove are adjacently formed together so as the surround the element region while seen from a plain view, wherein
step d) further comprises forming the second groove so as to overlap the second groove with the end portion of the first groove at the interface between the first groove and the second groove while seen from a plain view.

4. The method of a semiconductor device according to claim 1, wherein
step b) further comprises: forming the first groove near a region within a element region to be a channel region; and forming a gate electrode from an area directly above a region to be a channel region to another area directly above the first groove near the region to be a channel region, wherein
the length of the first groove along the first groove formed near the region to be the channel region is longer than the gate length of the gate electrode.
